(19) United States
(12) Patent Application Publication
(10) Pub. No.: US 2025/0105765 A1
(43) Pub. Date: Mar. 27, 2025

(54) CURRENT DETECTION METHOD, POWER TOOL, AND NON-TRANSITORY COMPUTER-READABLE MEDIUM

(71) Applicant: JIANGSU DONGCHENG TOOLS TECHNOLOGY CO., LTD., NANTONG (CN)

(72) Inventors: Chunlei LU, NANTONG (CN); Yan JIN, NANTONG (CN)

(21) Appl. No.: 18/725,774

(22) PCT Filed: Jun. 28, 2023
(86) PCT No.: PCT/CN2023/103420

§ 371 Date: Jun. 30, 2024

(30) Foreign Application Priority Data
Sep. 20, 2022 (CN) 202211140147.1

(51) Int. Cl. H02P 6/24

(52) U.S. Cl. CPC H02P 6/24

(57) ABSTRACT

A current detection method and a power tool are provided. The method includes: performing current sampling according to a time interval so as to acquire a plurality of current sampling values; sequentially storing the plurality of current sampling values into a storage queue with a length of N; determining a maximum value Iₘₐₓ and a minimum value Iₘᵢₙ in N current sampling values in the storage queue; and according to a difference value between Iₘₐₓ and Iₘᵢₙ, determining a current sudden change point. In the method, only the latest N current sampling values are stored in the storage queue, and the maximum value and the minimum value are compared so as to determine the current sudden change point.

### CROSS-REFERENCE TO RELATED APPLICATIONS

The present application is a 35 U.S.C. § 371 National Phase conversion of International (PCT) Patent Application No. PCT/CN2023/103420, filed Jun. 28, 2023, which claims priority to Chinese Patent Application No. 202211140147.1, filed Sep. 20, 2022, both of which are herein incorporated by reference in their entirety.

### TECHNICAL FIELD

The present disclosure relates to the technical field of power tools, and in particular to a current detection method and a power tool with a current detection function.

### BACKGROUND

Power tools rely on motors for operation, and control modules in the power tools, such as microcontroller units (MCU), achieve motor shutdown control through current detection. Taking electric wrenches as an example, the electric wrenches usually have a reverse self-stop function, which is controlled by the current detection. In response to a current sudden change point being detected, the motor is controlled to perform the reverse self-stop function. That is, by detecting whether the current is less than a fixed value or a constant value, it is judged whether the current has a sudden change. In response to the current changes being from greater than the fixed value to less than the fixed value, it is judged that the current has the sudden change. A point corresponding to the fixed value is the current sudden change point. A status of a device is identified and controlled by judging whether there is the current sudden change point. However, this judgment method has two problems: 1) if the fixed value is selected at a position a, as shown in FIG. 1, it is easy to cause misjudgment because it is close to a normal current value; 2) if the fixed value is selected at a position b, as shown in FIG. 1, it is not easy to cause misjudgment. However, because it takes a long time for the current to decrease to the position b, the delay in the judgment of a current sudden change time is large, and a real current sudden change point may be missed.

In order to further improve efficiency of determining a threshold value of an operating state of the device, Chinese Patent number 113283502 discloses: after determining historical operating state data corresponding to the device, dividing the historical operating state data into different states by clustering the historical operating state data; and then identifying a device state threshold based on difference value data corresponding to clusters between different states. That is, the device state threshold may be calculated only through historical data, which may effectively improve the efficiency of determining the operating state of the device. Although the above method may improve the efficiency of determining the operating state of the device, it requires the device to have strong processing capabilities. However, chips of general power tools have poor processing capabilities, and it is difficult for the chips to provide the processing capabilities required by the above method. High-performance chips may be used. However, the high-performance chips undoubtedly increase costs.

In view of this, it is indeed necessary to provide an improved power tool to overcome defects of the related art.

### SUMMARY OF THE DISCLOSURE

A current detection method is provided, and the method includes a sampling operation, a storing operation, and a processing operation.

The sampling operation is performing current sampling according to a time interval ΔT during operating the motor, to obtain a plurality of current sampling values.

The storing operation is storing the plurality of current sampling values in sequence into a storage queue with a length of N.

The processing operation is determining a maximum value Iₘₐₓ and a minimum value Iₘᵢₙ of N current sampling values in the storage queue, and determining a current sudden change point according to a difference value between Iₘₐₓ and Iₘᵢₙ.

In some embodiments, the method further includes: re-determining Iₘₐₓ and Iₘᵢₙ of the plurality of current sampling values in the storage queue in response to the plurality of current sampling values in the storage queue being updated, and determining the current sudden change point in response to the difference value between Iₘₐₓ and Iₘᵢₙ being greater than a preset threshold.

In some embodiments, the method further includes: determining a change period T of a current according to a waveform change of the current, and determining a preset time interval ΔT according to the length N of the storage queue and the change period T of the current.

In some embodiments, the change period T of the current, the length N of the storage queue, and the preset time interval ΔT satisfy the following relationship: N*ΔT<T.

In some embodiments, the storage queue is a first-in-first-out queue.

In some embodiments, the change period T of the current, the length N of the storage queue, and the preset time interval ΔT satisfy the following relationship: 0.5T<N*ΔT<T.

In some embodiments, the preset threshold is 5A, or 10% of a stable current during normal operation.

The present disclosure further provides a power tool. The power tool includes a processor and a memory that is configured to store a computer program run on the processor. In response to the processor executing the computer program, the method of any one of above embodiments is achieved.

The present disclosure further provides a non-transitory computer-readable medium having a non-volatile program code and executed by a processor. The program code allows the processor to execute the method of any one of above embodiments.

### BRIEF DESCRIPTION OF THE DRAWINGS

The embodiments of the present disclosure are further described in detail below in conjunction with the accompanying drawings.

FIG. 1 is a current waveform change trend view of a motor in the related art.

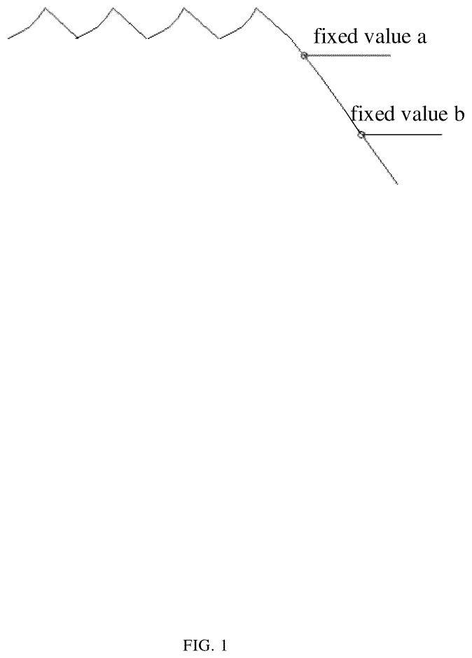

FIG. 2 is a flow chart of a method in some embodiments of the present disclosure.

FIG. 3 is a current waveform change trend view of a motor in some embodiments of the present disclosure.

FIG. 4 is a structure block view of a power tool in some embodiments of the present disclosure.

FIG. 5 is a circuit structure view of a power tool in some embodiments of the present disclosure.

### DETAILED DESCRIPTION

The present disclosure may be further described in detail below in conjunction with the accompanying drawings and embodiments.

The terms used in the present disclosure are only for the purpose of describing the embodiments and are not intended to limit the present disclosure.

In view of defects of the related art, a purpose of the present disclosure is to provide a power tool that has low-cost and is capable of achieving efficient threshold determination.

### Embodiment 1

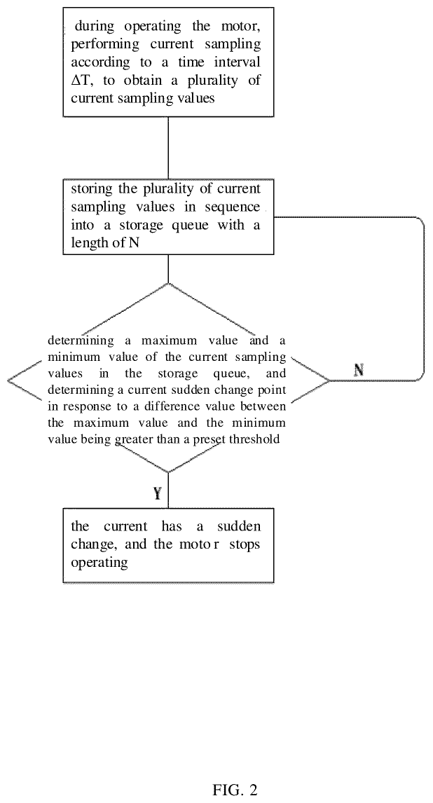

In view of defects of the related art, the present disclosure creatively provides a new current detection method based on characteristics of the current changes, which may accurately and timely obtain a current sudden change point, so that a microcontroller unit (MCU) may control a motor in a timely manner according to the current sudden change point. In some embodiments, the method may be applied to power tools, such as electric wrenches. Thus, the MCU may control the motor in a timely manner according to the current sudden change point, achieve a reverse self-stop function, and achieve the effect of stopping immediately once a bolt is loosened, so that the bolt is almost in direct contact with or fits snugly with the screw. As shown in FIG. 2, the current detection method includes the following operations.

The current detection method may include a sampling operation: during operating the motor, performing current sampling according to a time interval ΔT, to obtain a plurality of current sampling values.

The current detection method may include a storing operation: storing the plurality of current sampling values in sequence into a storage queue with a length of N.

The current detection method may include a processing operation: determining a maximum value Iₘₐₓ and a minimum value Iₘᵢₙ of N current sampling values in the storage queue, and determining the current sudden change point according to a difference value between Iₘₐₓ and Iₘᵢₙ.

In some embodiments, only the latest N current sampling values are stored in the storage queue, and the current sudden change point is determined by comparing the maximum value and the minimum value. The calculation is simple and the requirements for a MCU chip are low. Thus, the current detection may be achieved by using an existing chip, and current detection efficiency and accuracy of the current sudden change point may be improved.

In some embodiments, in response to the current sampling values in the storage queue being updated, the maximum value Iₘₐₓ and the minimum value Iₘᵢₙ of the current sampling values in the storage queue are re-determined. In response to the difference value between Iₘₐₓ and Iₘᵢₙ being greater than a preset threshold, the current sudden change point is determined. That is, the difference value between Iₘₐₓ and Iₘᵢₙ is greater than the preset threshold, which indicates that the current has a sudden change, thereby determining the current sudden change point. Since the current sudden change point usually occurs during continuous decrease of the current, the current sudden change point determined at this time is a current sampling point corresponding to updated Iₘᵢₙ. In some embodiments, in response to the current sudden change point being detected, a state conversion function is started, such as controlling the motor to perform the reverse self-stop function. Those skilled in the art obtains the highest current during startup, a stable current during stable operation, and a decreased current that is formed after the current continuously decreases for a certain period of time by testing the power tools such as the electric wrenches, so that the preset threshold is determined. In some embodiments, the preset threshold may be 5A, or 10% of the stable current during normal operation, etc. The stable current may be expressed by a rated current. The specific determination process is implemented by those skilled in the art in combination with existing experience and/or evaluation methods, functions, etc., which is a common method in the field and may not is repeated here.

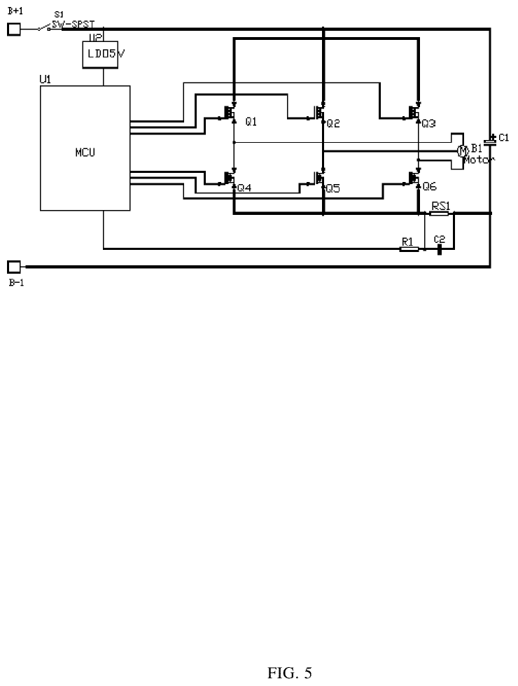

In the present disclosure, the storage queue is a first-in-first-out queue. In some embodiments, a length of the storage queue may be eight, which includes a first point of the storage queue, a second point of the storage queue, a third point of the storage queue, a fourth point of the storage queue, a fifth point of the storage queue, a sixth point of the storage queue, a seventh point of the storage queue, and an eighth point of the storage queue. In response to a S1 switch in FIG. 5 being closed, the motor starts to run, and the MCU controls the brushless motor to start running. At this time, the current sampling is performed, to obtain a first current sampling value. The first current sampling value is stored in the first point of the storage queue. After a fixed time interval, such as 5 ms, the current sampling is performed again to obtain the current sampling value, and this current sampling value is stored in the second point of the storage queue. The sampling operation and the storing operation are performed in sequence, until the third point of the storage queue, the fourth point of the storage queue, the fifth point of the storage queue, the sixth point of the storage queue, the seventh point of the storage queue, and the eighth point of the storage queue store data. The sampling operation continues to be performed, so that a new current sampling value is obtained, and the new current sampling value is stored in the eighth point of the storage queue. The current sampling value stored in the original eighth point of the storage queue is stored in the seventh point of the storage queue. The current sampling value stored in the original seventh point of the storage queue is stored in the sixth point of the storage queue, move forward in sequence until the current sampling value stored in the original second point of the storage queue is stored in the first point of the storage queue, thereby ensuring that the latest current sampling value is always stored in the eighth point of the storage queue. In some embodiments, the first point of the storage queue, the second point of the storage queue, the third point of the storage queue, the fourth point of the storage queue, the fifth point of the storage queue, the sixth point of the storage queue, the seventh point of the storage queue, and the eighth point of the storage queue are sequentially named as a first point of the queue storing the current sampling value, a second point of the queue storing the current sampling value, a third point of the queue storing the current sampling value, a fourth point of the queue storing the current sampling value, a fifth point of the queue storing the current sampling value, a sixth point of the queue storing the current sampling value, a seventh point of the queue storing the current sampling value, and an eighth point of the queue storing the current sampling value. It is determined whether there is the current sudden change point in the eight points of the queue storing the current sampling value. In some embodiments, a method for determining whether there is the current sudden change point in the eight points of the queue storing the current sampling value including: comparing the eight current sampling values, to obtain the maximum difference value; that is, obtaining the maximum value and the minimum value of the eight current sampling values, and obtaining the difference value between the maximum value and minimum value; and in response to the difference value being greater than the preset threshold, it is determined that current has the sudden change at this time; otherwise, it is determined that the current has not the sudden change. In some embodiments, whenever a new current is detected, the above operation is performed, to obtain the maximum value and the minimum value in the current queue, and then obtain the difference value between the maximum value and the minimum value. In response to the difference value being greater than the preset threshold, it is determined that the current has the sudden change at this time. A sampling point corresponding to the minimum value of the current sampling values at this time is the current sudden change point. Through the above method, it is possible to effectively prevent the misjudgment of the current sudden change point and improve the accuracy and timeliness of the determination.

Through the above method, using characteristics of the first-in-first-out storage queue, the latest current sampling value are stored. Then the maximum value and the minimum value are selected, and difference value calculation is performed, thereby determining the current sudden change point. The method is simple and the requirements for the processing capabilities of the MCU chip are low. Thus, the current detection may be achieved by using the existing chip. Moreover, the accuracy of identifying the current sudden change point may be significantly improved.

In some embodiments, the method further includes determining a change period T of the current according to a waveform change of the current, and determining a preset time interval ΔT according to the length N of the storage queue and the change period T of the current. The change period T of the current is set according to an interval period that is set according to actual operation requirements. The change period T of the current, the length N of the storage queue, and the preset time interval ΔT satisfy the following relationship: N*ΔT<T.

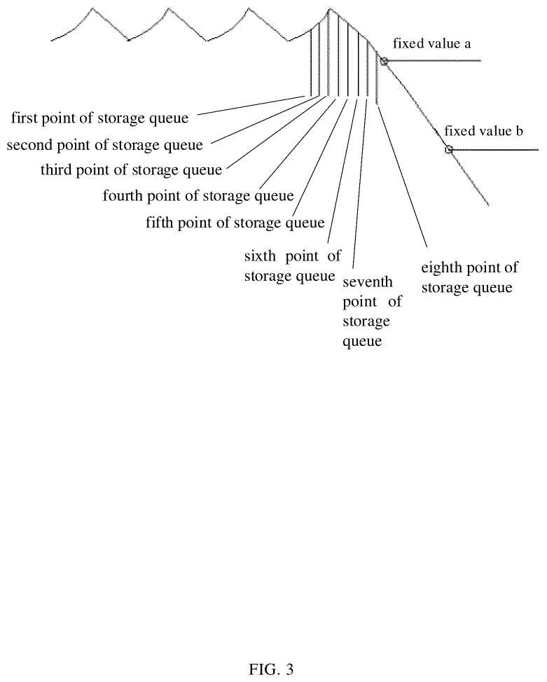

In the present disclosure, during the normal operation of the motor, a changing law of the current is identified, to obtain the change waveform of the current, as shown in FIG. 3. In some embodiments, an increasing process and a decreasing process of the current may be defined as one cycle, and accordingly, a value of the change cycle T of the current is determined. By the above relationship, a time length of the N current sampling values stored in the storage queue is limited to be less than one current change cycle, thereby improving the accuracy of sampling and the accuracy of the method.

In some embodiments, the change period T of the current, the length N of the storage queue, and the preset time interval ΔT may also satisfy the following relationship: 0.5T<N*ΔT<T. Through the above settings, it is ensured that the current sampling values stored in the storage queue may cover at least half of the current change cycle, preventing the misjudgment of the current sudden change point caused by the continuous decrease of the current due to the influence of the external environment, and further improving the accuracy of detection.

### Embodiment 2

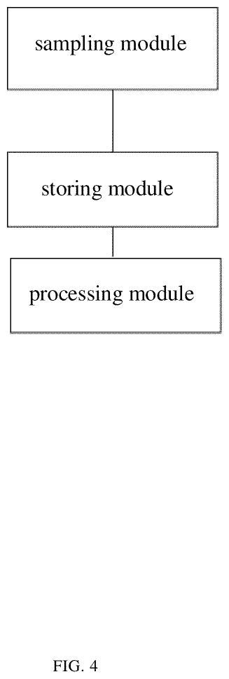

The present disclosure further provides a power tool having the current detection function as described in the example 1. As shown in FIG. 4, the power tool includes a sampling module, a storing module, and a processing module. The storing module may be an independent module or integrated into the processing module.

The sampling module is configured for performing current sampling according to the time interval ΔT during operating the motor, to obtain the plurality of current sampling values.

The storing module is configured for storing the plurality of current sampling values in sequence into the storage queue with the length of N.

The processing module is configured for determining the maximum value Iₘₐₓ and the minimum value Iₘᵢₙ of the current sampling values in the storage queue, and determining the current sudden change point according to the difference value between Iₘₐₓ and Iₘᵢₙ.

In some embodiments, only the latest N current sampling values are stored in the storage queue, and the current sudden change point is determined by comparing the maximum value and the minimum value. The calculation is simple and the requirements for the MCU chip are low. Thus, the current detection may be achieved by using the existing chip, and current detection efficiency and accuracy of the current sudden change point may be improved.

In some embodiments, in response to the current sampling values in the storage queue being updated, the maximum value Iₘₐₓ and the minimum value Iₘᵢₙ of the current sampling values in the storage queue are re-determined. In response to the difference value between Iₘₐₓ and Iₘᵢₙ being greater than the preset threshold, the current sudden change point is determined. That is, the difference value between Iₘₐₓ and Iₘᵢₙ is greater than the preset threshold, which indicates that the current has the sudden change, thereby determining the current sudden change point. Since the current sudden change point usually occurs during continuous decrease of the current, the current sudden change point determined at this time is the current sampling point corresponding to updated Iₘᵢₙ. In some embodiments, in response to the current sudden change point being detected, the state conversion function is started, such as controlling the motor to perform the reverse self-stop function. Those skilled in the art obtains the highest current during startup, the stable current during stable operation, and the decreasing current after the current continues to decrease for a certain period of time by testing the power tools such as the electric wrenches, so that the preset threshold is determined. In some embodiments, the preset threshold may be 5A, or 10% of the stable current during normal operation, etc. The stable current may be expressed by the rated current. The specific determination process is implemented by those skilled in the art in combination with existing experience and/or evaluation methods, functions, etc., which is the common method in the field and may not is repeated here.

In the present disclosure, the storage queue is the first-in-first-out queue. In some embodiments, the length of the storage queue may be eight, which includes the first point of the storage queue, the second point of the storage queue, the third point of the storage queue, the fourth point of the storage queue, the fifth point of the storage queue, the sixth point of the storage queue, the seventh point of the storage queue, and the eighth point of the storage queue. In response to the S1 switch in FIG. 5 being closed, the motor starts to run, and the MCU controls the brushless motor to start running. At this time, the current sampling is performed, to obtain the first current sampling value. The first current sampling value is stored in the first point of the storage queue. After the fixed time interval, such as 5 ms, the current sampling is performed again to obtain the current sampling value, and this current sampling value is stored in the second point of the storage queue. The sampling operation and the storing operation are performed in sequence, until the third point of the storage queue, the fourth point of the storage queue, the fifth point of the storage queue, the sixth point of the storage queue, the seventh point of the storage queue, and the eighth point of the storage queue store data. The sampling operation continues to be performed, so that the new current sampling value is obtained, and the new current sampling value is stored in the eighth point of the storage queue. The current sampling value stored in the original eighth point of the storage queue is stored in the seventh point of the storage queue. The current sampling value stored in the original seventh point of the storage queue is stored in the sixth point of the storage queue, move forward in sequence until the current sampling value stored in the original second point of the storage queue is stored in the first point of the storage queue, thereby ensuring that the latest current sampling value is always stored in the eighth point of the storage queue. In some embodiments, the first point of the storage queue, the second point of the storage queue, the third point of the storage queue, the fourth point of the storage queue, the fifth point of the storage queue, the sixth point of the storage queue, the seventh point of the storage queue, and the eighth point of the storage queue are sequentially named as the first point of the queue storing the current sampling value, the second point of the queue storing the current sampling value, the third point of the queue storing the current sampling value, the fourth point of the queue storing the current sampling value, the fifth point of the queue storing the current sampling value, the sixth point of the queue storing the current sampling value, the seventh point of the queue storing the current sampling value, and the eighth point of the queue storing the current sampling value. It is determined whether there is the current sudden change point in the eight points of the queue storing the current sampling value. In some embodiments, the method for determining whether there is the current sudden change point in the eight points of the queue storing the current sampling value including: comparing the eight current sampling values, to obtain the maximum difference value; that is, obtaining the maximum value and the minimum value of the eight current sampling values, and obtaining the difference value between the maximum value and minimum value; and in response to the difference value being greater than the preset threshold, it is determined that current has the sudden change at this time; otherwise, it is determined that the current has not the sudden change. In some embodiments, whenever the new current is detected, the above operation is performed, to obtain the maximum value and the minimum value in the current queue, and then obtain the difference value between the maximum value and the minimum value. In response to the difference value being greater than the preset threshold, it is determined that the current has the sudden change at this time. The sampling point corresponding to the minimum value of the current sampling values at this time is the current sudden change point. Through the above method, it is possible to effectively prevent the misjudgment of the current sudden change point and improve the accuracy and timeliness of the determination.

Through the above method, using characteristics of the first-in-first-out storage queue, the latest current sampling value are stored. Then the maximum value and the minimum value are selected, and difference value calculation is performed, thereby determining the current sudden change point. The method is simple and the requirements for the processing capabilities of the MCU chip are low. Thus, the current detection may be achieved by using the existing chip. Moreover, the accuracy of identifying the current sudden change point may be significantly improved.

In some embodiments, the method further includes determining the change period T of the current according to the waveform change of the current, and determining the preset time interval ΔT according to the length N of the storage queue and the change period T of the current. The change period T of the current is set according to an interval period that is set according to the actual operation requirements. The change period T of the current, the length N of the storage queue, and the preset time interval ΔT satisfy the following relationship: N*ΔT<T.

In the present disclosure, during the normal operation of the motor, the changing law of the current is identified, to obtain the change waveform of the current, as shown in FIG. 3. In some embodiments, the increasing process and the decreasing process of the current may be defined as one cycle, and accordingly, the value of the change cycle T of the current is determined. By the above relationship, the time length of the N current sampling values stored in the storage queue is limited to be less than one current change cycle, thereby improving the accuracy of sampling and the accuracy of the method.

In some embodiments, the change period T of the current, the length N of the storage queue, and the preset time interval ΔT may also satisfy the following relationship: 0.5T<N*ΔT<T. Through the above settings, it is ensured that the current sampling values stored in the storage queue may cover at least half of the current change cycle, preventing the misjudgment of the current sudden change point caused by the continuous decrease of the current due to the influence of the external environment, and further improving the accuracy of detection.

### Embodiment 3

The present disclosure further provides a power tool, and the power tool has the current detection function as described in the embodiment 1. As shown in FIGS. 5, Q1 to Q6 represents a N-channel MOS tube that is configured to control a brushless motor. RS1 represents a current sensing resistor that is configured to detect a running current of the motor. R1 and C2 form an RC filter circuit that is configured for filtering the current. C1 represents an electrolytic capacitor that is configured to absorb a peak current. U1 represents the MCU that is configured to control the brushless motor and the current sampling, a system control logic, etc. U2 represents a LDO stabilized power supply that is configured to provide 5V power supply to the MCU. S1 represents a main circuit control switch that is configured for controlling the system power on and the motor operation.

In order to improve the efficiency of current detection and the accuracy of the current sudden change point, the power tool includes a sampling circuit and the MCU.

The sampling circuit includes the current sensing resistor RS1, and is configured to detect the running current of the motor, so as to obtain the current sampling values.

The MCU is configured to control the brushless motor and the processing of the current sampling values, including setting the storage queue configured for storing the current sampling values into the storage queue in sequence, determining the maximum value Iₘₐₓ and the minimum value Iₘᵢₙ of the current sampling values in the storage queue, and determining the current sudden change point according to the difference value between Iₘₐₓ and Iₘᵢₙ.

In some embodiments, only the latest N current sampling values are stored in the storage queue, and the current sudden change point is determined by comparing the maximum value and the minimum value. The calculation is simple and the requirements for the MCU chip are low. Thus, the current detection may be achieved by using the existing chip, and current detection efficiency and accuracy of the current sudden change point may be improved.

In some embodiments, in response to the current sampling values in the storage queue being updated, the maximum value Iₘₐₓ and the minimum value Iₘᵢₙ of the current sampling values in the storage queue are re-determined. In response to the difference value between Iₘₐₓ and Iₘᵢₙ being greater than the preset threshold, the current sudden change point is determined. That is, the difference value between Iₘₐₓ and Iₘᵢₙ is greater than the preset threshold, which indicates that the current has the sudden change, thereby determining the current sudden change point. Since the current sudden change point usually occurs during continuous decrease of the current, the current sudden change point determined at this time is the current sampling point corresponding to updated Iₘᵢₙ. In some embodiments, in response to the current sudden change point being detected, the state conversion function is started, such as controlling the motor to perform the reverse self-stop function. Those skilled in the art obtains the highest current during startup, the stable current during stable operation, and the decreasing current after the current continues to decrease for a certain period of time by testing the power tools such as the electric wrenches, so that the preset threshold is determined. In some embodiments, the preset threshold may be 5A, or 10% of the stable current during normal operation, etc. The stable current may be expressed by the rated current. The specific determination process is implemented by those skilled in the art in combination with existing experience and/or evaluation methods, functions, etc., which is the common method in the field and may not is repeated here.

In the present disclosure, the storage queue is the first-in-first-out queue. In some embodiments, the length of the storage queue may be eight, which includes the first point of the storage queue, the second point of the storage queue, the third point of the storage queue, the fourth point of the storage queue, the fifth point of the storage queue, the sixth point of the storage queue, the seventh point of the storage queue, and the eighth point of the storage queue. In response to the S1 switch in FIG. 5 being closed, the motor starts to run, and the MCU controls the brushless motor to start running. At this time, the current sampling is performed, to obtain the first current sampling value. The first current sampling value is stored in the first point of the storage queue. After the fixed time interval, such as 5 ms, the current sampling is performed again to obtain the current sampling value, and this current sampling value is stored in the second point of the storage queue. The sampling operation and the storing operation are performed in sequence, until the third point of the storage queue, the fourth point of the storage queue, the fifth point of the storage queue, the sixth point of the storage queue, the seventh point of the storage queue, and the eighth point of the storage queue store data. The sampling operation continues to be performed, so that the new current sampling value is obtained, and the new current sampling value is stored in the eighth point of the storage queue. The current sampling value stored in the original eighth point of the storage queue is stored in the seventh point of the storage queue. The current sampling value stored in the original seventh point of the storage queue is stored in the sixth point of the storage queue, move forward in sequence until the current sampling value stored in the original second point of the storage queue is stored in the first point of the storage queue, thereby ensuring that the latest current sampling value is always stored in the eighth point of the storage queue. In some embodiments, the first point of the storage queue, the second point of the storage queue, the third point of the storage queue, the fourth point of the storage queue, the fifth point of the storage queue, the sixth point of the storage queue, the seventh point of the storage queue, and the eighth point of the storage queue are sequentially named as the first point of the queue storing the current sampling value, the second point of the queue storing the current sampling value, the third point of the queue storing the current sampling value, the fourth point of the queue storing the current sampling value, the fifth point of the queue storing the current sampling value, the sixth point of the queue storing the current sampling value, the seventh point of the queue storing the current sampling value, and the eighth point of the queue storing the current sampling value. It is determined whether there is the current sudden change point in the eight points of the queue storing the current sampling value. In some embodiments, the method for determining whether there is the current sudden change point in the eight points of the queue storing the current sampling value including: comparing the eight current sampling values, to obtain the maximum difference value; that is, obtaining the maximum value and the minimum value of the eight current sampling values, and obtaining the difference value between the maximum value and minimum value; and in response to the difference value being greater than the preset threshold, it is determined that current has the sudden change at this time; otherwise, it is determined that the current has not the sudden change. In some embodiments, whenever the new current is detected, the above operation is performed, to obtain the maximum value and the minimum value in the current queue, and then obtain the difference value between the maximum value and the minimum value. In response to the difference value being greater than the preset threshold, it is determined that the current has the sudden change at this time. The sampling point corresponding to the minimum value of the current sampling values at this time is the current sudden change point. Through the above method, it is possible to effectively prevent the misjudgment of the current sudden change point and improve the accuracy and timeliness of the determination.

The present disclosure further provides a power tool. The power tool includes a memory and a processor. The memory is configured to store a computer program that may be run on the processor. The processor is configured to execute the computer program, so as to implement the method in the embodiment 1.

The present disclosure further provides a non-transitory computer-readable medium having a non-volatile program code and executed by the processor. The program code enables the processor to execute the method described in the embodiment 1.

In the solution provided by the present disclosure, the current sampling is performed according to the time interval ΔT, to obtain the plurality of current sampling values. The plurality of current sampling values are stored in sequence into the storage queue with the length of N. The maximum value Iₘₐₓ and the minimum value Iₘᵢₙ of the N current sampling values in the storage queue are determined. The current sudden change point is determined based on the difference value between Iₘₐₓ and Iₘᵢₙ. In the present disclosure, only the latest N current sampling values are stored in the storage queue, and the current sudden change point is determined by comparing the maximum value and the minimum value. Thus, the current detection may be achieved by using the existing chip, thereby improving the efficiency of the current detection and the accuracy of determining the current sudden change point.

Those skilled in the art may clearly understand that for the convenience and simplicity of description, the specific operation processes of the system and device described above may refer to the corresponding processes in the foregoing method embodiments, and may not is repeated here.

When the functions are implemented in the form of software functional units and sold or used as independent products, the functions may be stored in the non-transitory computer-readable storage medium. Based on this understanding, the technical solution of the present disclosure, in essence, or the parts that contribute to the existing technology, or the parts of the technical solution, may be reflected in the form of software products. The computer software product is stored in a storage medium, including several instructions, configured for enabling a computer device (such as a personal computer, a server, or a network device, etc.) to perform all or part of the operations of the methods described in each embodiment of the present disclosure. The aforementioned storage media include various media that may store program codes, such as a USB flash drive, a mobile hard disk, a read-only memory (ROM), a random access memory (RAM), a magnetic disk, an optical disk, or the like.

The above-described embodiments are only specific implementations of the present disclosure, which are configured to illustrate the technical solutions of the present disclosure, rather than limiting the present disclosure. The protection scope of the present disclosure is not limited thereto. Although detailed explanations of the present disclosure have been provided with reference to the aforementioned embodiments, those skilled in the art should understand that any those skilled in the art may still modify or easily think of changes to the technical solution recorded in the aforementioned embodiments in the technical scope disclosed by the present disclosure, or make equivalent substitutions to some of the technical features. These modifications, changes, or replacements do not make the essence of the corresponding technical solution deviate from the spirit and scope of the technical solution in the embodiments of the present disclosure, and should be included in the protection scope of the present disclosure. Thus, the protection scope of the present disclosure should be subject to the protection scope of the claims.

1. A current detection method, comprising:
during operating the motor, performing current sampling according to a time interval ΔT, to obtain a plurality of current sampling values;
storing the plurality of current sampling values in sequence into a storage queue with a length of N; and
determining a maximum value Iₘₐₓ and a minimum value Iₘᵢₙ of N current sampling values in the storage queue, and determining a current sudden change point according to a difference value between Iₘₐₓ and Iₘᵢₙ.

2. The method according to claim 1, further comprising: re-determining Iₘₐₓ and Iₘᵢₙ of the plurality of current sampling values in the storage queue in response to the plurality of current sampling values in the storage queue being updated, and determining the current sudden change point in response to the difference value between Iₘₐₓ and Iₘᵢₙ being greater than a preset threshold.

3. The method according to claim 1, further comprising: determining a change period T of a current according to a waveform change of the current, and determining a preset time interval ΔT according to the length N of the storage queue and the change period T of the current.

4. The method according to claim 3, wherein the change period T of the current, the length N of the storage queue, and the preset time interval ΔT satisfy the following relationship: N*ΔT<T.

5. The method according to claim 1, wherein the storage queue is a first-in-first-out queue.

6-8. (canceled)

9. A power tool, comprising a processor and a memory that is configured to store a computer program run on the processor, wherein in response to the processor executing the computer program, a current detection method is performed, and the current detection method comprises:
during operating the motor, performing current sampling according to a time interval ΔT, to obtain a plurality of current sampling values;
storing the plurality of current sampling values in sequence into a storage queue with a length of N; and
determining a maximum value Iₘₐₓ and a minimum value Iₘᵢₙ of N current sampling values in the storage queue, and determining a current sudden change point according to a difference value between Iₘₐₓ and Iₘᵢₙ.

10. A non-transitory computer-readable medium having a non-volatile program code and executed by a processor, wherein the program code allows the processor to execute a current detection method, and the current detection method comprises:
during operating the motor, performing current sampling according to a time interval ΔT, to obtain a plurality of current sampling values;
storing the plurality of current sampling values in sequence into a storage queue with a length of N; and
determining a maximum value Iₘₐₓ and a minimum value Iₘᵢₙ of N current sampling values in the storage queue, and determining a current sudden change point according to a difference value between Iₘₐₓ and Iₘᵢₙ.

11. The method according to claim 3, wherein the change period T of the current, the length N of the storage queue, and the preset time interval ΔT satisfy the following relationship:
$$0.5 T < N * Δ T < T .$$

12. The method according to claim 2, wherein the preset threshold is 5A, or 10% of a stable current during normal operation.

13. The power tool according to claim 9, wherein the current detection method further comprises: re-determining Iₘₐₓ and Iₘᵢₙ of the plurality of current sampling values in the storage queue in response to the plurality of current sampling values in the storage queue being updated, and determining the current sudden change point in response to the difference value between Iₘₐₓ and Iₘᵢₙ being greater than a preset threshold.

14. The power tool according to claim 9, wherein the current detection method further comprises: determining a change period T of a current according to a waveform change of the current, and determining a preset time interval ΔT according to the length N of the storage queue and the change period T of the current.

15. The power tool according to claim 14, wherein the change period T of the current, the length N of the storage queue, and the preset time interval ΔT satisfy the following relationship:
$$N * Δ T < T .$$

16. The power tool according to claim 9, wherein the storage queue is a first-in-first-out queue.

17. The power tool according to claim 14, wherein the change period T of the current, the length N of the storage queue, and the preset time interval ΔT satisfy the following relationship:
$$0.5 T < N * Δ T < T .$$

18. The power tool according to claim 13, wherein the preset threshold is 5 A, or 10% of a stable current during normal operation.

19. The non-transitory computer-readable medium according to claim 10, wherein the current detection method further comprises: re-determining Iₘₐₓ and Iₘᵢₙ of the plurality of current sampling values in the storage queue in response to the plurality of current sampling values in the storage queue being updated, and determining the current sudden change point in response to the difference value between Iₘₐₓ and Iₘᵢₙ being greater than a preset threshold.

20. The non-transitory computer-readable medium according to claim 10, wherein the current detection method further comprises: determining a change period T of a current according to a waveform change of the current, and determining a preset time interval ΔT according to the length N of the storage queue and the change period T of the current.

21. The non-transitory computer-readable medium according to claim 20, wherein the change period T of the current, the length N of the storage queue, and the preset time interval ΔT satisfy the following relationship:
$$N * Δ T < T .$$

22. The non-transitory computer-readable medium according to claim 10, wherein the storage queue is a first-in-first-out queue.

23. The non-transitory computer-readable medium according to claim 20, wherein the change period T of the current, the length N of the storage queue, and the preset time interval ΔT satisfy the following relationship:
$$0.5 T < N * Δ T < T .$$
